(19) United States
(12) Patent Application Publication
(10) Pub. No.: US 2015/0311223 A1
(43) Pub. Date: Oct. 29, 2015

(54) THIN FILM TRANSISTOR ARRAY SUBSTRATE AND MANUFACTURING METHOD THEREOF, AND DISPLAY DEVICE

(71) Applicant: BOE TECHNOLOGY GROUP CO., LTD., Beijing (CN)

(72) Inventors: Fengjuan LIU, Beijing (CN); Meili WANG, Beijing (CN); Li ZHANG, Beijing (CN); Liangchen YAN, Beijing (CN)

(73) Assignee: BOE TECHNOLOGY GROUP CO., LTD., Beijing (CN)

(21) Appl. No.: 14/406,326

(22) PCT Filed: May 27, 2014
(86) PCT No.: PCT/CN2014/078546

§ 371 Date: Dec. 8, 2014

(30) Foreign Application Priority Data
Dec. 4, 2013 (CN) 201310648419.3

(51) Int. Cl. H01L 27/12; H01L 21/283; H01L 21/308; H01L 29/417; H01L 29/40; H01L 29/423; H01L 29/786; H01L 21/28; H01L 29/66

(52) U.S. Cl. CPC H01L 27/124; H01L 21/28008; H01L 21/283; H01L 21/3081; H01L 29/66742; H01L 29/401; H01L 29/42384; H01L 29/786; H01L 29/41733; H01L 27/1259

(57) ABSTRACT

A thin film transistor array substrate and a manufacturing method thereof, and a display device comprising the thin film transistor array substrate, including a gate electrode (4) within a gate electrode recess of a first insulating layer (2), so that the gate electrode (4) is surrounded by the first insulating layer (2), the patterned gate electrode (4) has no slope, and the first insulating layer (2) isolates the gate electrode (4) from the outside, which can prevent fracture of the gate insulating layer (5), and further effectively block copper diffusion in the thin film transistor array substrate. Further, the metal blocking layer completely covers an upper surface and/or a lower surface of the composite copper metal or the composite thin film layer including copper metal, which can play a good role in blocking copper diffusion; meanwhile, above all, it is not necessary to etch copper, which reduces cost and improves yield.

### TECHNICAL FIELD

Embodiments of the invention relate to a thin film transistor array substrate and a manufacturing method thereof, and a display device.

### BACKGROUND

Currently, scanning lines and data lines on a thin film transistor (briefly referred to as a TFT) array substrate of a display are fabricated generally by using relatively stable metals such as Ta, Mo and Cr or alloy materials such as AlNd. With development of display technology, a size of the display is constantly increased, and resolution is constantly improved, and products such as a large-screen television or a high-resolution monitor also require a smaller RC delay (i.e., a resistance/capacitance delay) of the scanning lines and the data lines, which requires scanning lines and data lines made of materials of lower resistivity.

Among metallic materials, copper has a lower resistivity, which is a preferable material able to replace existing materials of aluminum and aluminum alloy, to reduce the RC delay. However, there are still problems as follows when copper is used as a wiring material at present:

First, adhesion between copper and glass is weak, and copper atoms diffuse severely in a semiconductor and an oxide, so it is necessary to add a blocking layer respectively on the upper surface and the lower surface of copper, which may not only improve the adhesion of a copper conducting wire on glass, but also prevent copper diffusion. However, a certain slope angle is necessary for a patterned copper gate electrode to prevent fault of a gate insulating layer, which results in that the blocking layer cannot completely cover the upper surface of the copper thin film, and part of copper is still exposed outside a protective layer at the boundary.

Second, copper has poor etching capability, and it is very difficult to etch whether by wet etching or by dry etching. Etching effect is not ideal, and development cost of etching solutions is relatively high.

### SUMMARY OF THE INVENTION

An embodiment of the invention provides a manufacturing method of a thin film transistor array substrate, comprising steps of:

Forming a first insulating layer on a substrate, and forming a first photoresist layer on the first insulating layer, forming a gate electrode recess in the first insulating layer where the first photoresist layer has been formed, a periphery of the gate electrode recess being surrounded by the first insulating layer;

Forming a gate electrode layer on the substrate having the gate electrode recess;

Stripping the first photoresist layer on the substrate where the gate electrode layer has been formed and the gate electrode layer over the first photoresist layer, to form a gate electrode surrounded by the first insulating layer.

In one example, a gate insulating layer, an active layer, and a second insulating layer are sequentially formed on the substrate where the gate electrode surrounded by the first insulating layer has been formed;

a second photoresist layer is formed on the second insulating layer, a source electrode recess and a drain electrode recess are formed in the second insulating layer where the second photoresist layer has been formed, peripheries of the source electrode recess and the drain electrode recess being surrounded by the second insulating layer, and part of the active layer being exposed;

A source-drain electrode layer is formed on the substrate having the source electrode recess and the drain electrode recess;

The second photoresist layer formed on the substrate where the source-drain electrode layer has been formed and the source-drain electrode layer over the second photoresist layer are stripped, to form a source electrode and a drain electrode surrounded by the second insulating layer, the source electrode and the drain electrode being in contact with the active layer.

In one example, the forming a gate electrode recess in the first insulating layer where the first photoresist layer has been formed includes:

Forming a first photoresist layer reserved region and a first photoresist layer removed region by exposure and development, the first photoresist layer removed region corresponding to a position where the gate electrode recess is to be formed;

Etching the first insulating layer, the first insulating layer of the first photoresist layer removed region being etched to form the gate electrode recess.

In one example, the forming a source electrode recess and a drain electrode recess on the second insulating layer where the second photoresist layer has been formed, peripheries of the source electrode recess and the drain electrode recess being surrounded by the second insulating layer, and part of the active layer being exposed includes:

Forming a second photoresist layer reserved region and a second photoresist layer removed region by exposure and development, the second photoresist layer removed region corresponding to a position where the source electrode recess and the drain electrode recess are to be formed;

Etching the second insulating layer, the second insulating layer of the second photoresist layer removed region being etched to form the source electrode recess and the drain electrode recess.

In one example, a thickness of the gate electrode layer is formed to be equal to a depth of the gate electrode recess;

A thickness of the source-drain electrode layer is formed to be equal to a depth of the source electrode recess and the drain electrode recess.

In one example, the forming a gate electrode layer and/or forming a source-drain electrode layer includes:

Forming a metal layer or forming a metal conductive composite layer.

In one example, the forming a metal conductive composite layer includes:

Forming a copper metal thin film or forming an alloy thin film including copper metal; and

Forming at least one metal blocking layer located on at least one of the two opposite surfaces of the copper metal thin film or the alloy thin film including the copper metal;

Another embodiment of the invention provides a thin film transistor array substrate, comprising a substrate; and a gate electrode, a gate insulating layer, an active layer, a source electrode and a drain electrode sequentially formed on the substrate, a first insulating layer having a gate electrode recess being formed on the substrate, the gate electrode being formed within the gate electrode recess.

In one example, a second insulating layer having a source electrode recess and a drain electrode recess is formed on the gate insulating layer and the active layer, the source electrode and the drain electrode being respectively disposed within the source electrode recess and the drain electrode recess of the second insulating layer.

In one example, a thickness of the gate electrode layer is equal to a depth of the gate electrode recess.

In one example, a thickness of the source-drain electrode layer is equal to a depth of the source electrode recess and the drain electrode recess.

In one example, at least one of the gate electrode, the source electrode and the drain electrode includes a metal layer or a metal conductive composite layer.

In one example, the metal conductive composite layer includes a copper metal thin film or an alloy thin film including the copper metal, and at least one metal blocking layer located on at least one of two opposite surfaces of the copper metal thin film or the alloy thin film including the copper metal.

Yet another embodiment of the invention provides a display device, comprising the thin film transistor array substrate according to any embodiment described above.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a cross-sectional diagram after a first insulating layer is deposited on a substrate in an embodiment of the invention;

FIG. 2 is a cross-sectional diagram after a first photoresist layer is coated, and exposed and developed in an embodiment of the invention;

FIG. 3 is a cross-sectional diagram after the first insulating layer is etched in an embodiment of the invention;

FIG. 4 is a cross-sectional diagram after a gate electrode layer is deposited in an embodiment of the invention;

FIG. 5 is a cross-sectional diagram after the first photoresist layer and the gate electrode layer above the first photoresist layer are stripped in an embodiment of the invention;

FIG. 6 is a cross-sectional diagram after a gate insulating layer is deposited in an embodiment of the invention;

FIG. 7 is a cross-sectional diagram after an active layer is formed in an embodiment of the invention;

FIG. 8 is a cross-sectional diagram after a second insulating layer is formed in an embodiment of the invention;

FIG. 9 is a cross-sectional diagram after photoresist is coated on a second insulating layer, and is exposed and developed in an embodiment of the invention;

FIG. 10 is a cross-sectional diagram after the second insulating layer is etched in an embodiment of the invention;

FIG. 11 is a cross-sectional diagram after a source-drain electrode layer is deposited in an embodiment of the invention;

FIG. 12 is a cross-sectional diagram after a second photoresist layer and a source-drain electrode layer above the second photoresist are stripped in an embodiment of the invention.

### DESCRIPTION OF THE EMBODIMENTS

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

As illustrated in FIG. 12, a thin film transistor array substrate according to an embodiment of the invention comprises a substrate 1; and a gate electrode 4, a gate insulating layer 5, an active layer 6, a source electrode 9 and a drain electrode 10 sequentially formed on the substrate 1 from bottom to up. A first insulating layer 2 having a gate electrode recess is formed on the substrate 1, the gate electrode 4 is formed within the gate electrode recess, and the first insulating layer 2 can isolate the gate electrode 4 from the outside. The gate electrode 4 according to the embodiment of the present invention is formed within the gate electrode recess of the first insulating layer 2, so that the gate electrode is surrounded by the first insulating layer 2; the patterned gate electrode 4 has no slope, which can prevent fault of the gate insulating layer, and further effectively block copper diffusion in the thin film transistor (TFT) array substrate.

It should be noted that the substrate 1 mentioned in the embodiments of the invention can refer to a common substrate such as a glass substrate in general, or may be a substrate having other film layer or pattern formed thereon.

A second insulating layer 7 having a source electrode recess and a drain electrode recess is formed on the gate insulating layer 5 and the active layer 6, and the source electrode 9 and the drain electrode 10 are respectively formed within the source electrode recess and the drain electrode recess of the second insulating layer 7. The second insulating layer 7 is disposed in the peripheries of the source electrode 9 and the drain electrode 10, for isolating the source electrode 9 and the drain electrode 10 from the outside.

The gate electrode 4 and/or the source electrode 9 and the drain electrode 10 may include a metal layer or a metal conductive composite layer. For example, in order to improve a binding force between the gate electrode 4 and the substrate 1, the gate electrode 4 and/or the source electrode 9 and the drain electrode 10 include the metal conductive composite layer, the metal conductive composite layer including a copper metal thin film or an alloy thin film including copper metal; and at least one metal blocking layer located on an upper layer and/or a lower layer of the copper metal thin film or the alloy thin film including the copper metal, that is to say, the metal blocking layer is formed on at least one of the two opposite surfaces of the copper metal thin film or the alloy thin film including the copper metal.

For example, a thickness of the gate electrode 4 is equal to a depth of the gate electrode recess of the first insulating layer 2, and thicknesses of the source electrode 9 and the drain electrode 10 are equal to depths of the source electrode recess and the drain electrode recess of the second insulating layer 7.

In general, the metal blocking layer of the gate electrode 4 is located on the upper layer of the copper metal thin film or the alloy thin film layer including the copper metal, to block the Cu metal from diffusing into the gate insulating layer and the active layer. And the metal blocking layer of the source electrode 9 and the drain electrode 10 is located on the lower layer of the copper metal thin film or the alloy thin film layer including the copper metal, to block the Cu from diffusing into the second insulating layer 7 and the active layer 6. The metal blocking layers of the gate electrode 4 and the source electrode 9 and the drain electrode 10 are made of materials, for example, elementary metal such as Al, In, Ti, Ta and Mo and alloy thereof.

A display device according to an embodiment of the invention comprises the TFT array substrate provided by the above-described technical solution.

An embodiment of the invention further provides a manufacturing method of the thin film transistor array substrate provided by the above-described technical solution, comprising steps of:

Forming a first insulating layer 2 on a substrate 1, and forming a first photoresist layer 3 on the first insulating layer 2, forming a gate electrode recess in the first insulating layer 2 where the first photoresist layer 3 has been formed, a periphery of the gate electrode recess being surrounded by the first insulating layer;

Forming a gate electrode layer on the substrate 1 having the gate electrode recess;

Stripping the first photoresist layer 3 on the substrate where the gate electrode layer has been formed and the gate electrode layer above the first photoresist layer 3, to form a gate electrode 4 surrounded by the first insulating layer.

The steps of the manufacturing method of the thin film transistor array substrate according to the embodiment of the invention are described as follows:

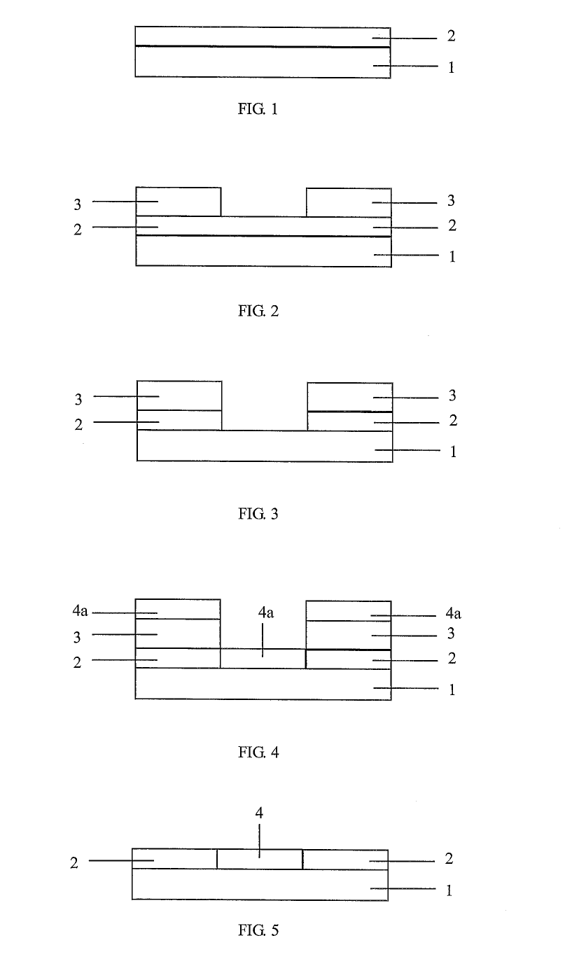

S1: As illustrated in FIG. 1 to FIG. 3, a first insulating layer 2 is formed on a substrate 1, wherein, a thickness of the first insulating layer 2 is equal to a thickness of the gate electrode and gate line metal composite layer as required, and a first photoresist layer 3 is formed on the first insulating layer 2 by a coating or spraying process, and a first photoresist layer reserved region and a first photoresist layer removed region are formed after exposure and development. The first photoresist layer removed region corresponds to a position where the gate electrode recess is to be formed. The first insulating layer 2 is etched with the patterned first photoresist layer as a mask, so that the first insulating layer in the first photoresist layer removed region is etched, to form the gate electrode recess; the periphery of the gate electrode recess is surrounded by the first insulating layer 2, and photoresist on the first insulating layer 2 in the periphery of the gate electrode recess is reserved to proceed with subsequent stripping of the gate electrode layer.

S2: As illustrated in FIG. 4, a gate electrode layer 4a is formed on the substrate 1 having the gate electrode recess by a deposition or sputtering process, at this time, both the gate electrode recess and the first photoresist layer in the periphery of the gate electrode recess are coated with the gate electrode layer 4a, the gate electrode layer 4a including a metal layer or a metal conductive composite layer, wherein, the metal conductive composite layer includes a copper metal thin film or a composite thin film layer comprising the copper metal, and at least one metal blocking layer located on an upper layer or a lower layer of the copper metal thin film or the composite thin film layer comprising the copper metal, to effectively block copper diffusion;

S3: As illustrated in FIG. 5, the substrate 1 having the gate electrode layer formed thereon is immersed in stripping solution, so that the photoresist thereon and the gate electrode layer over the photoresist are stripped, to form a gate electrode 4 surrounded by the first insulating layer 2, a thickness of the gate electrode 4 being equal to a depth of the gate electrode recess of the first insulating layer 2, so that a smooth surface is formed on the substrate 1, which process does not require copper etching;

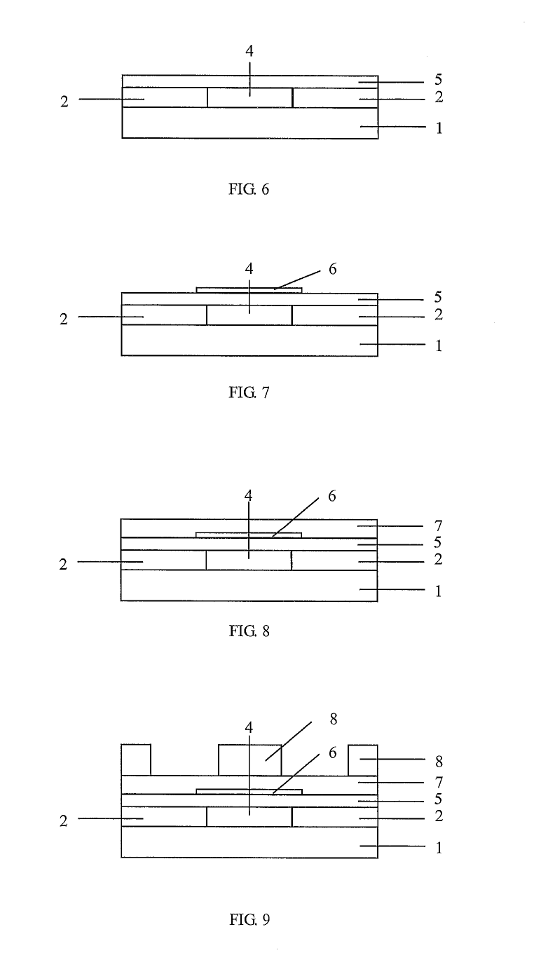

S4: As illustrated in FIG. 6 to FIG. 12, after a gate electrode 4 surrounded by the first insulating layer 2 is formed, a gate insulating layer 5, an active layer 6, a second insulating layer 7, a source electrode 9 and a drain electrode 10 are sequentially formed on the substrate 1. As illustrated in FIG. 6; after the gate electrode 4 surrounded by the first insulating layer 2 is formed, the gate insulating layer 5 is deposited on the substrate 1; and the active layer 6 is deposited on the gate insulating layer 5, as illustrated in FIG. 7, the active layer 6 is a patterned graph, which may include an amorphous or polycrystalline metal oxide semiconductor containing one or more metal elements such as indium (In), gallium (Ga), zinc (Zn), hafnium (Hf), tin (Sn), and aluminum (Al), for example, ZnO, InZnO(IZO), GaZnO(GZO), InGaZnO(IGZO), HfInZnO(HIZO), SnInO(ITO), ZnSnO(ZTO), AlInZnO(AIZO), etc., a channel layer of the TFT is formed by one patterning process, and finally the source electrode 9 and drain electrode 10 are formed, as illustrated in FIG. 8 to FIG. 12.

The process of forming the source electrode 9 and drain electrode 10 is that:

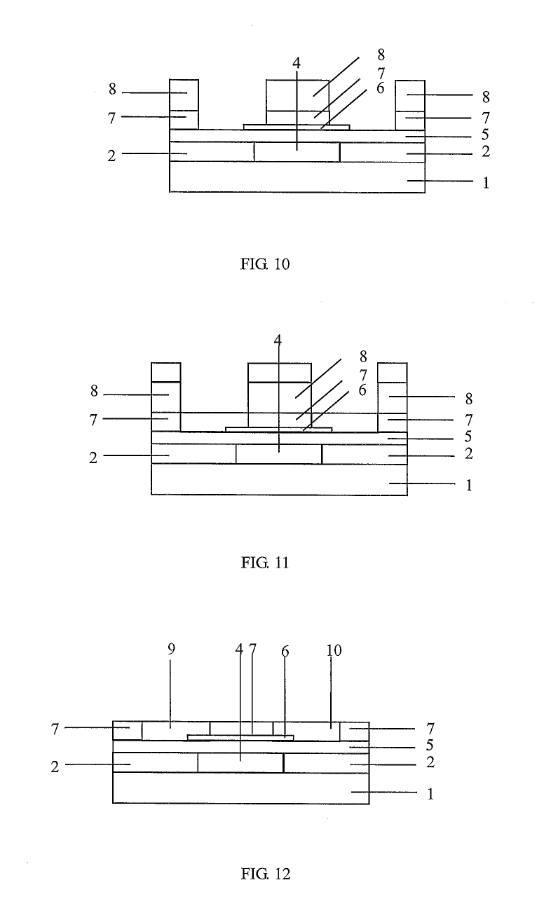

S10: As illustrated in FIG. 8, FIG. 9 and FIG. 10, the second insulating layer 7 is formed by a process such as deposition and sputtering on the substrate 1 where the active layer 6 has been formed, and a second photoresist layer 8 is formed on the second insulating layer 7 by a coating or spraying process, and after exposure and development, a second photoresist reserved region and a second photoresist removed region are formed. The second photoresist removed region corresponds to a position where the source electrode recess and the drain electrode recess are to be formed. The second insulating layer 7 is etched and patterned with the patterned second photoresist layer as a mask, the second insulating layer 7 of the second photoresist removed region is etched to finally form the source electrode recess and the drain electrode recess, part of the active layer 6 is exposed out of the source electrode recess and the drain electrode recess to be connected with the source electrode and the drain electrode formed subsequently, the periphery of the source electrode recess and the drain electrode recess is surrounded by the second insulating layer 7, wherein, the photoresist on the second insulating layer 7 in the periphery of the source electrode recess and the drain electrode recess is reserved to proceed with subsequent stripping of the source-drain electrode layer, which process does not require copper etching; wherein, the second insulating layer 7 includes one or more of silicon oxide, nitride and oxynitride;

S20: As illustrated in FIG. 11, a source-drain electrode layer is formed on the substrate 1 having the source electrode recess and the drain electrode recess by a deposition and sputtering process, the source-drain electrode layer is a metal layer or a metal conductive composite layer, wherein the metal conductive composite layer includes the copper metal thin film or the composite thin film layer including the copper metal, and at least one metal blocking layer located on the upper layer or the lower layer of the copper metal thin film or the composite thin film layer including the copper metal, to effectively block copper diffusion;

S30: As illustrated in FIG. 12, the substrate 1 having the source-drain electrode layer formed thereon is immersed in the stripping solution, so that the second photoresist layer thereon and the source-drain electrode layer over the second photoresist layer are stripped, to form the source electrode 9 and the drain electrode 10 surrounded by the second insulating layer 7; thicknesses of the source electrode 9 and the drain electrode 10 are equal to depths of the source electrode recess and the drain electrode recess of the second insulating layer, so that a smooth surface is formed on the substrate, to finally complete the manufacturing of the whole TFT array substrate.

In the TFT array substrate and the manufacturing method thereof, and the display device comprising the TFT array substrate provided by the embodiments of the invention, the gate electrode is formed within the gate electrode recess of the first insulating layer, so that the gate electrode is surrounded by the first insulating layer, the patterned gate electrode has no slope, which can prevent fracture of the gate insulating layer, and further effectively block copper diffusion in the TFT array substrate; and the metal blocking layer completely covers the upper surface and/or the lower surface of the composite copper metal thin film or the gate electrode containing copper metal or source-drain electrode composite thin film layer including the copper metal, which can play a good role in blocking copper diffusion; meanwhile, above all, it is not necessary to etch copper, which reduces cost and improves yield.

The foregoing embodiments merely are exemplary embodiments of the invention, and not intended to define the scope of the invention, and the scope of the invention is determined by the appended claims.

The present application claims priority of Chinese Patent Application No. 201310648419.3 filed on Dec. 4, 2013, and the above Chinese patent application is incorporated herein by reference in its entirety as part of the present application.

1. A manufacturing method of a thin film transistor array substrate, comprising steps of:
forming a first insulating layer on a substrate, and forming a first photoresist layer on the first insulating layer, forming a gate electrode recess in the first insulating layer where the first photoresist layer has been formed, a periphery of the gate electrode recess being surrounded by the first insulating layer;
forming a gate electrode layer on the substrate having the gate electrode recess;
stripping the first photoresist layer on the substrate where the gate electrode layer has been formed and the gate electrode layer over the first photoresist layer, to form a gate electrode surrounded by the first insulating layer.

2. The manufacturing method of the thin film transistor array substrate according to claim 1, wherein,
a gate insulating layer, an active layer, and a second insulating layer are sequentially formed on the substrate where the gate electrode surrounded by the first insulating layer has been formed;
a second photoresist layer is formed on the second insulating layer, a source electrode recess and a drain electrode recess are formed in the second insulating layer where the second photoresist layer has been formed, peripheries of the source electrode recess and the drain electrode recess being surrounded by the second insulating layer, and part of the active layer being exposed;
a source-drain electrode layer is formed on the substrate having the source electrode recess and the drain electrode recess;
the second photoresist layer formed on the substrate where the source-drain electrode layer has been formed and the source-drain electrode layer over the second photoresist layer are stripped, to form a source electrode and a drain electrode surrounded by the second insulating layer, the source electrode and the drain electrode being in contact with the active layer.

3. The manufacturing method of the thin film transistor array substrate according to claim 2, wherein, the forming a gate electrode recess in the first insulating layer where the first photoresist layer has been formed includes:
forming a first photoresist layer reserved region and a first photoresist layer removed region by exposure and development, the first photoresist layer removed region corresponding to a position where the gate electrode recess is to be formed;
etching the first insulating layer, the first insulating layer of the first photoresist layer removed region being etched to form the gate electrode recess.

4. The manufacturing method of the thin film transistor array substrate according to claim 2, wherein,
the forming a source electrode recess and a drain electrode recess on the second insulating layer where the second photoresist layer has been formed, peripheries of the source electrode recess and the drain electrode recess being surrounded by the second insulating layer, and part of the active layer being exposed includes:
forming a second photoresist layer reserved region and a second photoresist layer removed region by exposure and development, the second photoresist layer removed region corresponding to a position where the source electrode recess and the drain electrode recess are to be formed;
etching the second insulating layer, the second insulating layer of the second photoresist layer removed region being etched to form the source electrode recess and the drain electrode recess.

5. The manufacturing method of the thin film transistor array substrate according to claim 2, wherein,
a thickness of the gate electrode layer is formed to be equal to a depth of the gate electrode recess;
a thickness of the source-drain electrode layer is formed to be equal to a depth of the source electrode recess and the drain electrode recess.

6. The manufacturing method of the thin film transistor array substrate according to claim 2, wherein,
the forming a gate electrode layer and/or forming a source-drain electrode layer includes:
forming a metal layer or forming a metal conductive composite layer.

7. The manufacturing method of the thin film transistor array substrate according to claim 6, wherein,
the forming a metal conductive composite layer includes:
forming a copper metal thin film or forming an alloy thin film including copper metal; and
forming at least one metal blocking layer located on at least one of two opposite surfaces of the copper metal thin film or the alloy thin film including the copper metal;

8. A thin film transistor array substrate, comprising a substrate; and a gate electrode, a gate insulating layer, an active layer, a source electrode and a drain electrode sequentially formed on the substrate, a first insulating layer having a gate electrode recess being formed on the substrate, the gate electrode being formed within the gate electrode recess.

9. The thin film transistor array substrate according to claim 8, wherein, a second insulating layer having a source electrode recess and a drain electrode recess is formed on the gate insulating layer and the active layer, the source electrode and the drain electrode being respectively disposed within the source electrode recess and the drain electrode recess of the second insulating layer.

10. The thin film transistor array substrate according to claim 8, wherein,
a thickness of the gate electrode layer is equal to a depth of the gate electrode recess.

11. The thin film transistor array substrate according to claim 9, wherein,
a thickness of the source-drain electrode layer is equal to a depth of the source electrode recess and the drain electrode recess.

12. The thin film transistor array substrate according to claim 8, wherein, at least one of the gate electrode, the source electrode and the drain electrode includes a metal layer or a metal conductive composite layer.

13. The thin film transistor array substrate according to claim 12, wherein, the metal conductive composite layer includes a copper metal thin film or an alloy thin film including the copper metal, and at least one metal blocking layer located on at least one of two opposite surfaces of the copper metal thin film or the alloy thin film including the copper metal.

14. A display device, comprising the thin film transistor array substrate according to claim 8.

15. The manufacturing method of the thin film transistor array substrate according to claim 3, wherein,
the forming a source electrode recess and a drain electrode recess on the second insulating layer where the second photoresist layer has been formed, peripheries of the source electrode recess and the drain electrode recess being surrounded by the second insulating layer, and part of the active layer being exposed includes:
forming a second photoresist layer reserved region and a second photoresist layer removed region by exposure and development, the second photoresist layer removed region corresponding to a position where the source electrode recess and the drain electrode recess are to be formed;
etching the second insulating layer, the second insulating layer of the second photoresist layer removed region being etched to form the source electrode recess and the drain electrode recess.

16. The manufacturing method of the thin film transistor array substrate according to claim 3, wherein,
a thickness of the gate electrode layer is formed to be equal to a depth of the gate electrode recess;
a thickness of the source-drain electrode layer is formed to be equal to a depth of the source electrode recess and the drain electrode recess.

17. The manufacturing method of the thin film transistor array substrate according to claim 4, wherein,
a thickness of the gate electrode layer is formed to be equal to a depth of the gate electrode recess;
a thickness of the source-drain electrode layer is formed to be equal to a depth of the source electrode recess and the drain electrode recess.

18. The manufacturing method of the thin film transistor array substrate according to claim 3, wherein,
the forming a gate electrode layer and/or forming a source-drain electrode layer includes:
forming a metal layer or forming a metal conductive composite layer.

19. The thin film transistor array substrate according to claim 9, wherein,
a thickness of the gate electrode layer is equal to a depth of the gate electrode recess.

20. The thin film transistor array substrate according to claim 9, wherein, at least one of the gate electrode, the source electrode and the drain electrode includes a metal layer or a metal conductive composite layer.
